(19) United States
(12) Patent Application Publication
(10) Pub. No.: US 2006/0003487 A1
(43) Pub. Date: Jan. 5, 2006

(54) Low power consumption OLED material for display applications

(75) Inventor: David B. Chung, Cupertino, CA (US)

Correspondence Address: TROUTMAN SANDERS LLP, BANK OF AMERICA PLAZA, SUITE 5200, 600 PEACHTREE STREET , NE, ATLANTA, GA, 30308-2216, US

(73) Assignee: Intel Corporation, Santa Clara, CA (US)

(21) Appl. No.: 10/881,691

(22) Filed: Jun. 30, 2004

(51) Int. Cl. H01L 21/00

(52) U.S. Cl. 438/82; 438/69

(57) ABSTRACT

Some embodiments of the present invention are directed to OLED materials useful in display devices and processes for making such OLED materials. The OLED materials may comprise polar compounds integrated with one or more substrates. When the polar compounds are simultaneously cured and exposed to an applied voltage or electric field, the polar compounds may be oriented in the direction of the voltage. Such orientation may result in the light emitted from the OLED material radiating in a single direction. Additional embodiments are directed to a system comprising a display device having a polar light-emitting layer whose dipoles are oriented in a single direction.

### BACKGROUND OF THE INVENTION

Liquid crystal displays (LCDs) are commonly used in devices such as flat panel displays for laptop computers, personal digital assistants, cellular phones, and the like. Displays made with LCDs frequently use a cold cathode fluorescent lamp (CCFL) or similar devices as a backlight for the LCD display to show forth an optical image to the viewer. CCFLs and similar devices are fragile, relatively inefficient materials that require an inverter and consume large quantities of power, up to 35 percent of the power within a notebook computer system. The use of CCFLs, which are made of glass or other rigid materials, renders the display module fragile, difficult to manufacture and maintain, and expensive to repair when broken. The specifications of these materials also render the display itself bulky and add to the weight of the system which incorporates the display. Because the displays are typically used in portable devices, users desire devices which are more ruggedized with lighter weight.

In an effort to reduce the weight of the display and increase its durability, some manufacturers use organic light emitting diode (OLED) materials as a backlight source in mobile devices. OLEDs are thin film materials which emit light when excited by electric current. Since OLEDs emit light of different colors, they could be used to make displays. Displays made from OLED materials, therefore, do not need additional backlights, thus eliminating the need for the fragile glass CCFL and hence the bulky form factor of the display module. OLEDs are usually lightweight and can operate efficiently at relatively low voltages, thus consuming less power from the system. The versatility of the light emitting OLED materials has led some manufacturers to believe it would be desirable to substitute them for LCDs in mobile display devices in the near future.

Although OLEDs can generate light with high efficiency, more than half of the light can be trapped within the device and render the light as useless for the device. Because the light emission from the OLED has no preference in the emitting direction, light is therefore emitted equally in all directions so that some of the light is emitted forward to the viewer, some is emitted to the back of the device and is either reflected forward to the viewer or being absorbed by the ambient, and some of the light is emitted laterally and trapped and absorbed by the various layers comprising the device. In general, up to 80% of the light generated from the OLED materials may be lost within the system and may never reach the viewer.

There is a need therefore for an improved organic light emitting diode display structure that avoids the problems noted above and improves the efficiency of power used by the display, especially in portable devices. The present invention is directed to a new way of improving power efficiency of organic emitting diode displays through modification of the device fabrication with respect to the OLED material.

### BRIEF DESCRIPTION OF THE DRAWINGS

FIG. 1 shows an OLED structure.

FIG. 2 shows an OLED structure having a grooved substrate.

FIG. 3 shows an OLED structure integrated with a display device.

### DETAILED DESCRIPTION OF THE INVENTION

Some embodiments of the present invention are directed to OLED structures useful in display devices and processes for making such OLED structures. The OLED structures may comprise polar compounds which possess certain dielectric anisotropy and can be aligned with respect to either one or more substrates of the display cell. When the polar compounds are exposed to an applied voltage or electric field, the polar compounds will respond and the molecule aligns in certain orientation with respect to the direction of the electric field or voltage. Such orientation can be calibrated in a manner that may result in the light emitted from the OLED material radiating in a certain dominant direction.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

An exemplary embodiment of the present invention includes an OLED material comprising polar functional groups and entities as their molecular components which, when subjected to an electric field, orient in a dominant direction as dictated by the electric field, thus orienting the emitted light in a single particular direction.

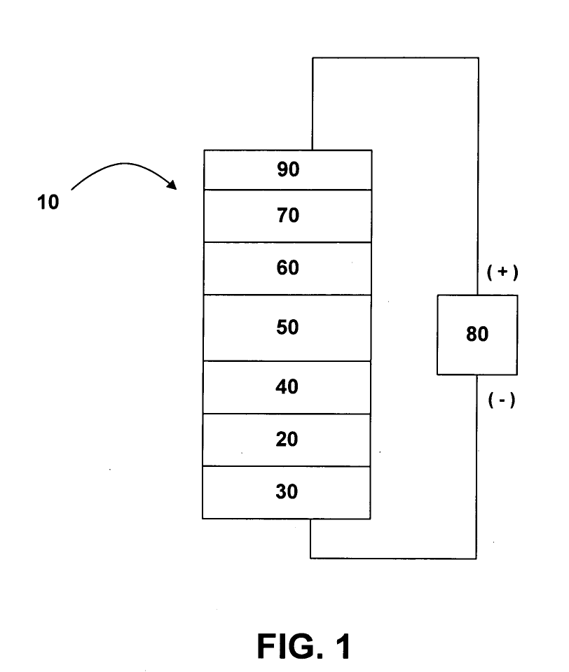

Turning now to the figures, in which like numerals refer to like elements through the several figures, FIG. 1 (not to scale) illustrates the structure of an OLED material 10 in accordance with some embodiments of the present invention. In an OLED structure 10, an anode coated conductive layer 20 may be integrated on a substrate 30. A hole-transport layer 40 may be stacked on the coating of the anode. A layer of polar light-emitting material 50 may be disposed on the hole-transport layer 40. An electron transport layer 60 may be disposed on the light-emitting layer 50. Finally, a substrate 90 may support a cathode 70 comprising a conductive film. A cathode 70 may additionally be disposed on the electron transport layer 60. The anode 20 and cathode 70 may be connected to a power source 80. When the power source is activated, holes are injected from anode 20 into hole transport layer 40, the holes combine in a light emitting layer 50 with electrons that travel from cathode 70 and generate visible light.

The substrates 30 and 90 may be made from any material capable of supporting the conductive coating of the anode 20 and cathode 70 and may be flexible or rigid. Examples include, but are not limited to, plastic, glass, quartz, plastic films, metals, ceramics, polymers or the like. Non-limiting examples of flexible plastic film and plastic include a film or sheet of polyethylene terephthalate (PET), polyethylene naphthalate (PEN), polyethersulfon (PES), polyetherimide, polyetheretherketone, polyphenylene sulfide, polyarylate, polyimide, polycarbonate (PC), cellulose triacetate (TAC), and cellulose acetate-propionate. Additionally, the substrate material 30 is transparent or otherwise light transmissive so that the light generated from the OLED material may pass through the device and be visible.

The anode coated conductive layer 20 may be formed by optionally coating the substrate with a transparent and conductive coating material. For example, and not for limitation, transparent and conductive coating materials may include indium-tin oxide (ITO), indium-zinc oxide (IZO), and other tin oxides such as, but not limited to, aluminum- or indium-doped zinc oxide, magnesium-indium oxide, nickel-tungsten oxide, metal nitrides, such as but not limited to gallium nitride, and metal selenides, such as but not limited to zinc selenide, and metal sulfides, such as but not limited to zinc sulfide.

Atop the anode coated conductive layer 20 is a hole transporting material 40. The hole-transporting material may include amines, such as but not limited to aromatic tertiary amines. In one form the aromatic tertiary amine may be an arylamine, such as but not limited to a monoarylamine, diarylamine, triarylamine, or a polymeric arylamine. In addition, polymeric hole-transporting materials may include poly(N-vinylcarbazole) (PVK), polythiophenes, polypyrrole, polyaniline, and copolymers such as poly(3,4-ethylenedioxythiophene)/poly(4-styrenesulfonate) also called PEDOT/PSS.

A polar light-emitting layer 50 is formed on hole transport layer 40 and may comprise a polar fluorescent and/or phosphorescent material where electroluminescence is produced as a result of electron-hole pair recombination in this region. The polar light-emitting layer 50 can be comprised of a single material or a host material doped with a guest compound or compounds, where light emission comes primarily from the dopant and can be of any color. In an exemplary embodiment, the light-emitting layer emits white light. The host material in the polar light-emitting layer 50 can be an electron-transporting material, as defined below, a hole-transporting material, as defined above, or another material or combination of materials that support hole-electron recombination. The dopant may be chosen from highly fluorescent dyes, but phosphorescent compounds, e.g., transition metal complexes, are also useful. Iridium complexes of phenylpyridine and its derivatives are particularly useful luminescent dopants. The polar light-emitting layer 50 may include dyes or coumarins and may also be polymeric material in nature. Polymeric materials such as polyfluorenes and polyvinylarylenes (e.g., poly(p-phenylenevinylene) (PPV)) can also be used as the host material. Small molecule dopants can be molecularly dispersed into the polymeric host, or the dopant could be added by copolymerizing a minor constituent into the host polymer. Any polar luminescent dopant known to be useful by one of ordinary skill in the art may be used herein.

An electron transport layer 60 is formed atop the polar light-emitting layer 50. The electron transporting material may be any material known to one of ordinary skill in the art to be useful for this purpose. Such compounds help to inject and transport electrons, exhibit high levels of performance, and are readily fabricated in the form of thin films. For example, and not for limitation, metal chelated oxinoid compounds, including chelates of oxine itself (also commonly referred to as 8-quinolinol or 8-hydroxyquinoline), may be used.

Finally, a cathode 70 is deposited on electron transport layer 60 and supported by a substrate 90. The cathode may be transparent or otherwise light transmissive, opaque, or reflective and can comprise nearly any conductive material. Suitable cathode materials have good film-forming properties to ensure good contact with the underlying organic layer, promote electron injection at low voltage, and have good stability. Useful cathode materials often contain a low work function metal (<4.0 eV) or metal alloy.

As noted above, substrate 90 may be made from any material capable of supporting the conductive coating of the cathode 70 and may be flexible or rigid. Examples include, but are not limited to, plastic, glass, quartz, plastic films, metals, ceramics, polymers or the like. Non-limiting examples of flexible plastic film and plastic include a film or sheet of polyethylene terephthalate (PET), polyethylene naphthalate (PEN), polyethersulfon (PES), polyetherimide, polyetheretherketone, polyphenylene sulfide, polyarylate, polyimide, polycarbonate (PC), cellulose triacetate (TAC), and cellulose acetate-propionate. Additionally, the substrate material 90 may be transparent or otherwise light transmissive, opaque, reflective or variations thereof.

When a potential, i.e. voltage, is applied to the device from a power source 80, electrons are emitted from light-emitting layer 50 where they are injected into electron transport layer 60 and recombined with the holes present therein giving rise to light emission. The cathode 70 reflects the light generated back toward the organic layers. By using multicolored OLED panels known to one of ordinary skill in the art, a white light or images with partial or full color utilizing field sequential color techniques may be formed.

Exemplary OLED materials of the present invention comprise polar light-emitting layer materials. By exposing the polar light-emitting layer materials to an electric field or applied voltage, the polar light-emitting layer polarizes, i.e., lines up, in the direction of the electric field. Such polarization orients the polar materials in a certain orientation and directs the light emitted from the light-emitting layer in a uniform dominant direction, thus optimizing the light emitted and reducing problems associated with light scatter and channeling. The polarity of the material may come from the organic light emitting material itself, the dopant host material, or the dopant. Chemical compounds useful as a light-emitting material, dopant host material, or dopant include those noted above as well as those known to one of ordinary skill in the art. Non-limiting examples of organic light-emitting materials include amines, including the aromatic tertiary amines, including arylamines, such as but not limited to a monoarylamine, diarylamine, triarylamine, or a polymeric arylamine polyimides, and polythiophenes including, but not limited to, poly(N-vinylcarbazole) (PVK), polypyrrole, polyaniline, and copolymers such as poly(3,4-ethylenedioxythiophene)/poly(4-styrenesulfonate) also called PEDOT/PSS and other amines referenced above.

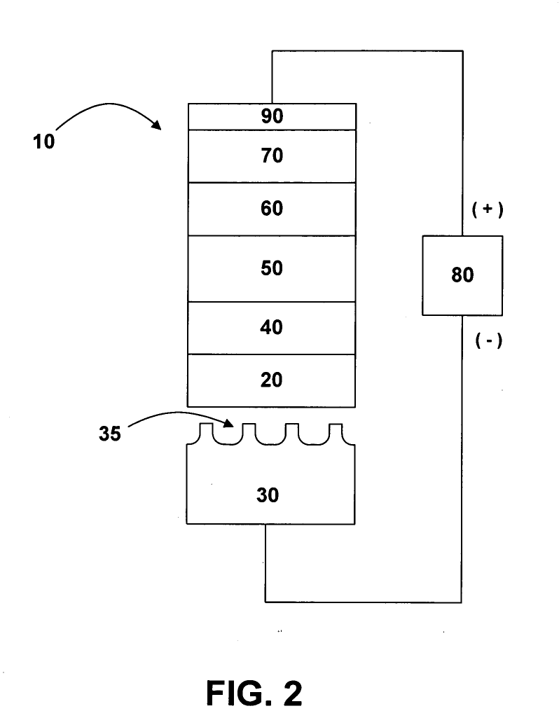

Another exemplary embodiment of the present invention may be shown in FIG. 2 (not to scale). In an OLED structure 10, an anode coated conductive layer 20 may be integrated on a substrate 30 having an irregular, non-smooth surface 35, also known as an alignment layer. The alignment layer 35 may provide an irregular, non-smooth surface for the subsequent layers. A hole-transport layer 40 may be applied on the coating of the anode 20 and upon the alignment layer 35. A layer of polar light-emitting material 50 may be disposed on the hole-transport layer 40. An electron transport layer 60 may be disposed on the light-emitting layer 50. Finally, a cathode 70 comprising a conductive film may be supported on a substrate 90 and disposed on the electron transport layer 60. The irregular, non-smooth surface of the alignment layer 35 may carry through the deposition process and exist at within all layers of the OLED structure. For example, the light-emitting layer 50 may fill part of the irregular surface of the alignment layer 35. In one embodiment, the polar light-emitting compounds may fill the alignment layer with portions of the molecules extending below the surface of the alignment layer and portions of the molecule extending above the surface of the alignment layer. The anode 20 and cathode 70 may be connected to a power source 80, which generates an applied voltage. When the power source is activated, holes may be injected from anode 20 into hole transport layer 40, the holes may combine in the light emitting layer 50 with electrons that travel from the cathode 70 and generate visible light. Because the light-emitting layer molecules are polar, the applied voltage causes the dipoles of the molecules to orient in a uniform arrangement, e.g., all positive ends of the molecule will be anchoring onto the surface of the alignment layer and all negative ends of the molecule will be pointing away from the surface of the alignment layer or vice-versa during the curing process.

Once the chemicals are applied to the alignment layer 35 or the substrate 30, the chemicals may undergo a curing process. During curing, a voltage is simultaneously applied to the OLED material, aligning the polar light-emitting compounds in all of the layers of the OLED material. The voltage facilitates the alignment of the dipoles of the light-emitting layer within the material during the curing cycle.

The applied voltage used to orient the light-emitting dipoles is typically less than about 7 volts. In one embodiment, the voltage ranges from 1 to about 7 volts. In another embodiment, the voltage ranges from about 3 volts to about 5 volts.

The irregular, non-smooth surface of the alignment layer 35 may be formed on the substrate 30 by any means known in the art. A non-limiting example of forming the irregular, non-smooth surface of the alignment layer 35 includes the rubbing process or friction transfer. Friction transfer includes preparing the alignment layer by pressing a solid structure, for example and not for limitation, pellets, bars, ingots, rods, sticks, or the like, of the alignment material against the substrate and drawing the solid alignment material across the structure in a selected direction under a pressure sufficient to transfer a thin layer of the alignment material onto the substrate. The selected direction of the friction transfer provides an orientation direction fro the alignment of subsequent layers. The substrate may optionally be heated to optimize the initial action of the alignment layer.

The thickness of the alignment layer may be sufficient to impart alignment on subsequent layers. The thickness may be thin enough such that the layer is not completely insulating. Exemplary thicknesses of the alignment layer of the present invention range from 0.1 to 20 microns. One embodiment of the invention provides for an alignment layer with thickness of between 1 to 10 microns, and still another embodiment provides for an alignment layer with thickness of between 5-7 microns.

The thickness of the polar light-emitting materials may range from 100 angstroms to 2000 angstroms. In one embodiment of the present invention, the thickness of the polar light-emitting layer ranges from 300 to 2000 angstroms. In another embodiment, the thickness of the polar light-emitting layer ranges from 800 to 2000 angstroms.

The polar light-emitting compound 50 may be applied to the irregular, non-smooth surface of the alignment layer 35 of which the topology shows through layer 20 and 40 or to the surface of the substrate 30 at room temperature or under elevated temperatures to enhance the uniformity of the light-emitting compound layer.

Other embodiments of the present invention include processes for preparing OLED materials useful in display devices. One exemplary process is illustrated in FIG. 2 and may include coating a substrate 30 with a conductive layer 20 and/or a hole transport layer 40 to form a coated substrate, rubbing the coated substrate to form grooves or other irregular surfaces of an alignment layer 35, applying a polar light-emitting compound 50 to the irregular surface of the coated substrate and filling the grooves or irregularities formed by rubbing the substrate with the light-emitting compound 50, then curing the coated substrate while simultaneously exposing it to an electric field.

Another exemplary process of the present invention may include coating a substrate 30 with a conductive layer 20 and/or a hole transport layer 40 to form a coated substrate, applying a polar light-emitting compound 50 to the surface of the coated substrate, then curing the coated substrate while simultaneously exposing it to an electric field.

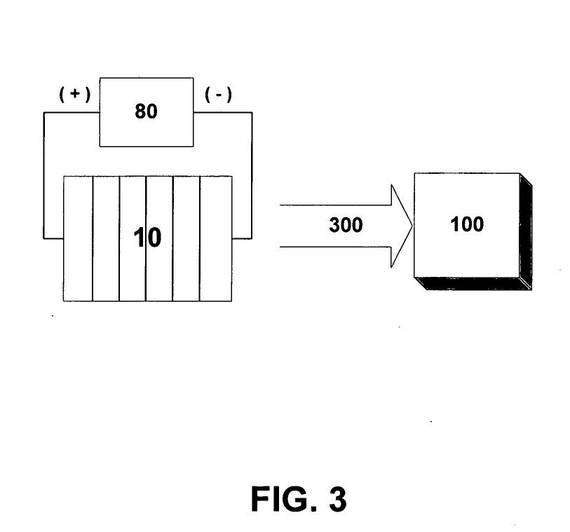

Another exemplary embodiment of the present invention may include the OLED materials integrated into a display device. FIG. 3 (not to scale) illustrates this exemplary embodiment. When a voltage is applied to the OLED structure 10 from a power source 80, light 300 emitted from the OLED structure 10 is transmitted in the direction of the applied voltage and toward the display 100. Because more of the light emitted from the OLED structure 10 is transmitted to the viewer, the display 100 may operate with less power than displays currently known in the art.

The display device may include light distributing devices, such as lenses, polarizers, or optical viewing elements. Integrated with the OLED materials of the present invention, the display 100 may be any element which transmits the light from the OLED to the viewer. The display 100 may also comprise other components such as, but not limited to, a processor, memory, power supplies, or other peripheral devices, either alone or in combination.

Those skilled in the art will appreciate that other light distributing devices may be used, such as, for example, and not for limitation, light guides, prisms, lenses, Fresnel lenses, diffusers, interferometers, or any other optical element that can distribute white light uniformly and efficiently onto the display device. It is further disclosed that additional optical elements, such as but not limited to polarizers, refractive elements, diffractive elements, bandpass filters, and the like, may be easily positioned exterior to or otherwise located near the OLED structure 10. By using a plurality of OLED panels as the light source, the size of the OLED structure 10 may be further reduced and the electrical power required may also be minimized. By using multicolored OLED panels, a white light or images with partial or full color utilizing field sequential color techniques may be formed. The light may optionally be passed through a light distributing device, which disperses the light to uniformly illuminate the display device 100.

Those skilled in the art will further appreciate that the OLED structure 10 of the present invention may optionally be present in a display device 100 in combination with other OLED structures. The OLED structure 10 may be arranged randomly or in a pattern and may be stacked or arranged in series or adjacent to one another. The arrangement of the OLED structure 10 may depend on any of several factors including, but not limited to, size of the display, lighting requirements for the display, color, and the like. Additionally, those skilled in the art will appreciate that OLED materials may be, for example, and not for limitation, strips, films, blocks, and the like.

The light emitted from the OLED structure 10 of the present invention may be manipulated by the structure of the OLED structure 10 itself and may emit white light or colors. A color-emitting OLED may be combined with white light-emitting OLED, both of which may then be incorporated into a display device 100.

In the embodiments of the present invention, the intensity of the light transmitted to the display device 100 and the intensity of the color may be varied by adjusting the current and driving voltages applied to the OLED structure 10. Proportional current changes may be applied to each layer of the stack or to each OLED structure 10 in the series to optionally vary the color perceived by the viewer.

The current necessary to display light from the OLED structure 10 to a display device 100 may be less than about 15 volts. In one embodiment of the present invention, the current necessary to display light from the OLED structure 10 ranges from about 1 volt to about 12 volts. The intensity of the light displayed from the OLED structure 10 may be varied by varying the voltage applied to the OLED structure 10.

The OLED structure 10 of the present invention may be incorporated into any system benefiting from an image display device. The OLED structure 10 of the present invention may be incorporated into a display device in addition to or in lieu of LCD displays or other display devices known in the art. Systems incorporating display devices include, but are not limited to, those used with laptop computers, personal digital assistants, cellular phones, and the like.

In addition to the display device 100, the system may also include, but is not limited to, a processing unit, a system memory, and a system bus that couples various system components including the system memory to the processing unit. The system bus may be any of several types of bus structures including a memory bus or memory controller, a peripheral bus, and a local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus also known as Mezzanine bus.

The system memory may include computer storage media in the form of volatile and/or nonvolatile memory such as read only memory (ROM) and random access memory (RAM). A basic input/output system (BIOS), containing the basic routines that help to transfer information between elements within the system, such as during start-up, is typically stored in ROM. RAM typically contains data program modules, and/or computer-executable instructions that are immediately accessible to and/or presently being operated on by processing unit.

While the present invention has been particularly shown and described with respect to exemplary embodiments thereof, it will be understood by those skilled in the art that the foregoing and other changes in form and detail may be made without departing from the scope and spirit of the present invention. It is therefore intended that the present invention not be limited to the exact forms described and illustrated, but fall within the scope of the appended claims.

1. A process for preparing Organic Light Emitting Diode (OLED) structure comprising:
a. coating a substrate with a conductive material to form an anode;
b. coating the anode with a hole-transport material to form a coated substrate;
c. optionally applying friction to the coated substrate to form an irregular surface alignment layer;
d. applying a polar organic compound to the surface of the coated substrate, and optionally allowing the polar organic compound to fill the irregular surface alignment layer formed in (c), to form a treated coated substrate;
e. curing the treated coated substrate while simultaneously exposing the treated coated substrate to an electric field.

2. The process of claim 1, wherein the treated coated substrate is exposed to an electric field of less than 5 volts during the curing of the treated coated substrate.

3. The process of claim 1, comprising:
a. coating a substrate with a conductive material to form an anode;
b. coating the anode with a polyimide material to form a coated substrate;
c. applying friction to the coated substrate to form an irregular surface alignment layer;
d. applying a polar organic compound to the surface of the coated substrate, and allowing the polar organic compound to fill the grooves formed in (c), to form a treated coated substrate;
e. curing the treated coated substrate while simultaneously exposing the treated coated substrate to an electric field.

4. The process of claim 1, wherein the exposure of the coated substrate to an electric field aligns the polar organic compound in a single orientation.

5. The process of claim 1 wherein the electric field is between about 1 and about 7 volts.

6. An apparatus comprising an organic light emitting diode structure comprising:
a. an anode integrated onto an anode substrate and connected to a power source;
b. a conductive layer coated onto the anode;
c. a hole-transport material coated onto the anode to form a coated substrate;
d. an optional irregular surface alignment layer formed on the coated substrate;
e. a polar organic compound applied to the surface of the coated substrate, and optionally filling in the irregular surface alignment layer in (c), to form a treated coated substrate;
f. an electron transport layer disposed on the polar organic compound;
g. a cathode disposed on the electron transport layer and supported by a cathode substrate;
h. a power source connected to the anode and the cathode, wherein, when voltage is applied to the anode and cathode from the power source, dipoles of the polar organic compound orient in a uniform direction.

7. The apparatus of claim 6, wherein the anode is coated with a polyimide material to form a coated substrate.

8. The apparatus of claim 6, wherein the anode substrate and the cathode substrate are selected from glass, plastic, quartz, plastic film, metal, ceramic, and polymers.

9. The apparatus of claim 6, wherein the conductive layer is selected from the group consisting of indium-tin oxide, indium-zinc oxide, aluminum-doped zinc oxide, indium-doped zinc oxide, magnesium-indium oxide, nickel-tungsten oxide, gallium nitride, zinc selenide and zinc sulfide.

10. The apparatus of claim 6, wherein the hole transport material is selected from the group consisting of monoarylamines, diarylamines, triarylamines, polymer arylamines, poly(N-vinylcarbazole), polythiophenes, polypyrroles, polyanilines, and copolymers thereof.

11. The apparatus of claim 6, wherein the polar organic compound is selected from the group consisting of fluorescent dyes, phosphorescent compounds, transition metal complexes, iridium complexes of phenylpyridine, coumarins, polyfluorenes, and polyvinylarylenes.

12. The apparatus of claim 6, wherein the electron transport layer is a metal chelated oxinoid compound.

13. A system, comprising:
a central processing unit operable to execute at least one set of maeline-readable instructions;
a memory storage device operable to share the machine-readable instruction; and
a display device comprising an OLED structure comprising at least one polar light emitting layer containing dipoles oriented in a single direction, wherein the display device is operable to display images in response to the set of machine-readable instructions.

14. The system of claim 13, wherein the OLED structure comprises:
a. an anode integrated onto an anode substrate and connected to a power source;
b. a conductive layer coated onto the anode;
c. a hole-transport material coated onto the anode to form a coated substrate;
d. an optional irregular surface alignment layer formed on the coated substrate;
e. a polar organic compound applied to the surface of the coated substrate, and optionally filling in the irregular surface alignment layer in (c), to form a treated coated substrate;
f. an electron transport layer disposed on the polar organic compound;
g. a cathode disposed on the electron transport layer and supported by a cathode substrate;
h. a power source connected to the anode and the cathode, wherein, when voltage is applied to the anode and cathode from the power source, dipoles of the polar organic compound orient in a uniform direction.

15. The system of claim 14, wherein the anode is coated with a polyimide material to form a coated substrate.

16. The system of claim 14, wherein the anode substrate and the cathode substrate are selected from glass, plastic, quartz, plastic film, metal, ceramic, and polymers.

17. The system of claim 14, wherein the conductive layer is selected from the group consisting of indium-tin oxide, indium-zinc oxide, aluminum-doped zinc oxide, indium-doped zinc oxide, magnesium-indium oxide, nickel-tungsten oxide, gallium nitride, zinc selenide and zinc sulfide.

18. The system of claim 14, wherein the hole transport material is selected from the group consisting of monoarylamines, diarylamines, triarylamines, polymer arylamines, poly(N-vinylcarbazole), polythiophenes, polypyrroles, polyanilines, and copolymers thereof.

19. The system of claim 14, wherein the polar organic compound is selected from the group consisting of fluorescent dyes, phosphorescent compounds, transition metal complexes, iridium complexes of phenylpyridine, coumarins, polyfluorenes, and polyvinylarylenes.

20. The system of claim 14, wherein the electron transport layer is a metal chelated oxinoid compound.

21. The process of claim 3, wherein the exposure of the coated substrate to an electric field aligns the polar organic compound in a single orientation.

22. The process of claim 3, wherein the electric field is between about 1 and about 7 volts.
